(19) United States
(12) Patent Application Publication
(10) Pub. No.: US 2009/0284313 A1
(43) Pub. Date: Nov. 19, 2009

(54) AUDIO AMPLIFIER

(76) Inventor: Chih-Haur Huang, Sinshih Township (TW)

Correspondence Address: HAYES SOLOWAY P.C., 3450 E. SUNRISE DRIVE, SUITE 140, TUCSON, AZ, 85718, US

(21) Appl. No.: 12/123,326

(22) Filed: May 19, 2008

(51) Int. Cl. H03F 3/38

(52) U.S. Cl. 330/10; 381/94.5

(57) ABSTRACT

An audio amplifier, amplifying the audio signal, includes a first filtering circuit, and a second filtering circuit. The first filtering circuit generates an inverting driving voltage to drive a load according to the audio signal. The second filtering circuit generates a non-inverting driving voltage to drive the load according to the inverting driving voltage. The first filtering circuit and the second filtering circuit filter out signals with frequencies greater than a pre-determined frequency.

### BACKGROUND

1. Field of Invention

The present invention relates to a power amplifier. More particularly, the present invention relates to a power amplifier for amplifying an audio signal.

2. Description of Related Art

As the name suggests, the audio amplifier amplifies audio signals. Audio amplifiers typically include an audio input stage which is connected to some type of audio source, and an audio output stage which is connected to audio devices. Audio amplifiers receive audio signals from the audio source, amplify those audio signals, generate audio current signals based on those amplified signals, and output the audio current signals to the audio devices to play the audio signal. The audio current signals drive the audio device and cause the audio device to reproduce the audio signals that are generated by the audio source to create sound.

To amplify the audio signal, the audio amplifier typically requires a bias circuit to provide the bias voltages for biasing the amplifying circuit. However, when the audio amplifier just powers on, the power source, such as the supply voltage, is suddenly delivered to the bias circuit, and the bias voltage generated by the bias circuit vibrates a lot at that moment. As a result, and the output audio signal generated according to the bias voltage vibrates a lot as well, which might damage the audio amplifier and produce an unpleasant pop noise.

Therefore, there is a need for a new audio amplifier which can prevent the pop noise, and prevent the amplifier circuit from being damaged when the audio amplifier powers on or powers down.

### SUMMARY

According to one embodiment of the present invention, an audio amplifier, amplifying the audio signal, includes a first filtering circuit, and a second filtering circuit. The first filtering circuit generates an inverting driving voltage to drive a load according to the audio signal, in which the first filtering circuit filters out signals with frequencies greater than a pre-determined frequency. The second filtering circuit generates a non-inverting driving voltage to drive the load according to the inverting driving voltage, in which the second filtering circuit filters out signals with frequencies greater than the pre-determined frequency.

According to another embodiment of the present invention, a method for generating an output audio signal is disclosed. The method includes determining a pre-determined frequency; filtering an input audio signal according to the pre-determined frequency to generate an inverting driving voltage, in which the input audio signal with frequency greater than the pre-determined frequency is filtered out; filtering the inverting driving voltage to generate a non-inverting driving voltage; and generating the output audio signal according to the inverting driving voltage and the non-inverting driving voltage.

It is to be understood that both the foregoing general description and the following detailed description are by examples, and are intended to provide further explanation of the invention as claimed.

### BRIEF DESCRIPTION OF THE DRAWINGS

These and other features, aspects, and advantages of the present invention will become better understood with regard to the following description, appended claims, and accompanying drawings where:

FIG. 1 shows the block diagram of the audio amplifier according to one embodiment of the present invention;

FIG. 2 shows the audio amplifier according to another embodiment of the present invention;

FIG. 3 shows the flow chart of method for playing the audio signal according to the embodiment of the present invention; and

FIG. 4 shows the power down signal waveform and the output audio signal waveform of the audio amplifier according to the embodiment of the present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

The filtering circuit of the embodiments shown below can filter out the signal with frequency greater than the pre-determined frequency, such that the pop noise of the output audio signal can be eliminated.

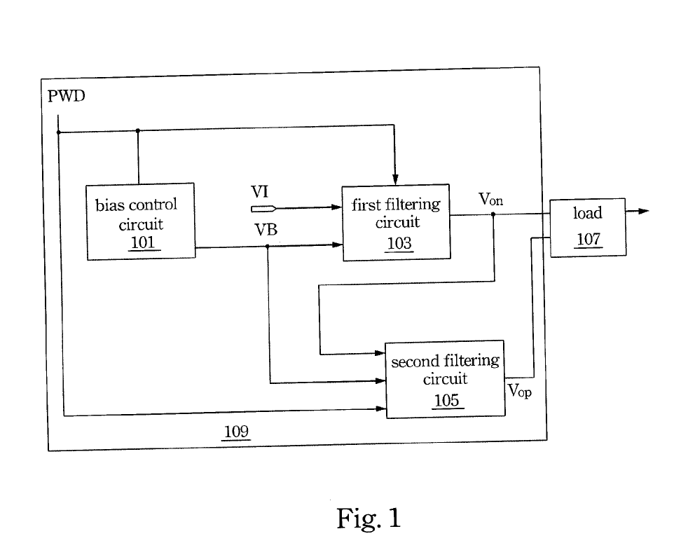

FIG. 1 shows the block diagram of the audio amplifier according to one embodiment of the present invention. The audio amplifier 109, amplifying an audio signal VI, includes the first filtering circuit 103 and the second filtering circuit 105. The first filtering circuit 103 generates an inverting driving voltage Von to drive a load 107 according to the audio signal VI. Because the first filtering circuit 103 can filter out signals with frequencies greater than a pre-determined frequency and amplifies the audio signals with desired frequency, the pop noise with a frequency greater than the pre-determined frequency is filtered out and not passed to the load 107. Therefore, the pop noises can be eliminated.

The second filtering circuit 105 generates the non-inverting driving voltage Vop to drive the load 107 according to the inverting driving voltage Von. Similar to the first filtering circuit 103, the second filtering circuit 105 can also further filter out the signals with frequencies greater than the pre-determined frequency and further amplifies the audio signals with desired frequency, so the pop noise with the frequency greater than the pre-determined frequency is not passed to the load 107. Therefore, the pop noises can be eliminated.

The audio amplifier 109 further includes the bias control circuit 101. The bias control circuit 101 provides at least one bias voltage VB for the first filtering circuit 103 and the second filtering circuit 105 to bias the first filtering circuit 103 and the second filtering circuit 105. In other words, the bias circuit 101 controls the voltage gain and the current gain of the first filtering circuit 103 and the second filtering circuit 105. By tuning the bias voltage VB properly, the input audio signal VI can be amplified to a desired scale.

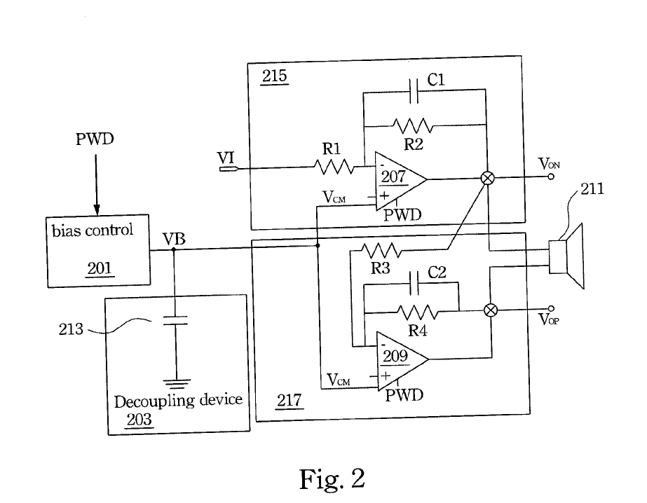

FIG. 2 shows the audio amplifier according to another embodiment of the present invention. The audio amplifier includes the first filtering circuit 215, the second filtering circuit 217, and the bias control circuit 201. The bias control circuit 201 provides at least one bias voltage VB for the first filtering circuit 215 and the second filtering circuit 217 to bias the first filtering circuit 215 and the second filtering circuit 217.

The first filtering circuit 215 generates the inverting driving voltage Von to drive the load according to the audio signal VI. The audio device here is a speaker 211. The first filtering circuit 215 includes the first operation amplifier 207, the first resistor R1, the second resistor R2, and the first capacitor C1. The first resistor R1 has one end receiving the audio signal VI and the other end connected to the negative terminal of the first operation amplifier 207. The first capacitor C1 and the second resistor R2 connect between the negative terminal and the output terminal of the first operation amplifier 207.

The first operation amplifier 207 receives the input audio signal VI and the common voltage V_{CM} which might be the supply voltage or the ground voltage. The first operation amplifier 207 generates the inverting driving voltage Von according to the audio signal VI. The capacitance of the first capacitor C1, the resistances of the first resistor R1 and the second resistor R2 determine the pre-determined frequency which determine the passing frequency of the audio signal. In other words, by tuning the capacitance of the first capacitor C1, the resistances of the first resistor R1 and the first resistor R2, signal with certain frequency can be filtered out, such as the pop noise.

The second filtering circuit 117 includes the second operation amplifier 209, the second capacitor C2, the third resistor R3, and the fourth resistor R4. The second capacitor C2 and the fourth resistor R4 connect between the negative terminal and the output terminal of the second operation amplifier 209. The third resistor R3 has one end receiving the inverting driving voltage Von and the other end connected to the negative terminal of the second operation amplifier 209.

The second operation amplifier 209 receives the inverting driving voltage Von and the common voltage V_{CM} which might be the supply voltage or the ground voltage. The second operation amplifier 209 generates the non-inverting driving voltage Vop according to the inverting driving voltage Von. Similar to the first filtering circuit 215, the capacitance of the second capacitor C2, the resistances of the third resistor R3 and the fourth resistor R4 determine the pre-determined frequency which determine the passing frequency of the audio signal. In other words, by tuning the capacitance of the second capacitor C2, the resistances of the third resistor R3 and the fourth resistor R4 properly, signal with certain frequency can be filtered out, such as that the pop noise caused when the audio amplifier is powered on or powered down can be filtered out.

The first operation amplifier 207 and the second operation amplifier 209 can be class AB amplifiers, the class B amplifier, or a class A amplifier. The class A amplifier power transistors are in a conductive state all the time, which means that the power transistors continuously dissipate power. Thereby, the class A amplifier has low power efficiency.

The class B amplifier has its power transistors successively driven between the conductive and the non-conductive states, therefore, the power transistors of the class B amplifier operate only 50% of the time. The class AB amplifier power transistors are in the conductive state for a time period greater than one-half of the total period. Thereby, the power transistors of the Class AB amplifier operate somewhere between 50% and the whole time period. As a result, because the Class AB amplifier and the Class B amplifier have better power efficiency, they are used more often in the audio amplifier than class A amplifier.

The audio amplifier further includes a decoupling device 203. The decoupling device 203 includes a decoupling capacitor 213 having one end coupled to the bias control circuit 201 and the other end receiving the ground voltage (or the supply voltage). The decoupling device 203 reduces the damping phenomenon of the bias voltage VB caused when the audio amplifier is powered on or powered down. By reducing the damping phenomenon of the bias voltage VB, the audio amplifier can be more stable, and the pop noises can be further reduced when the audio amplifier is powered on or powered down.

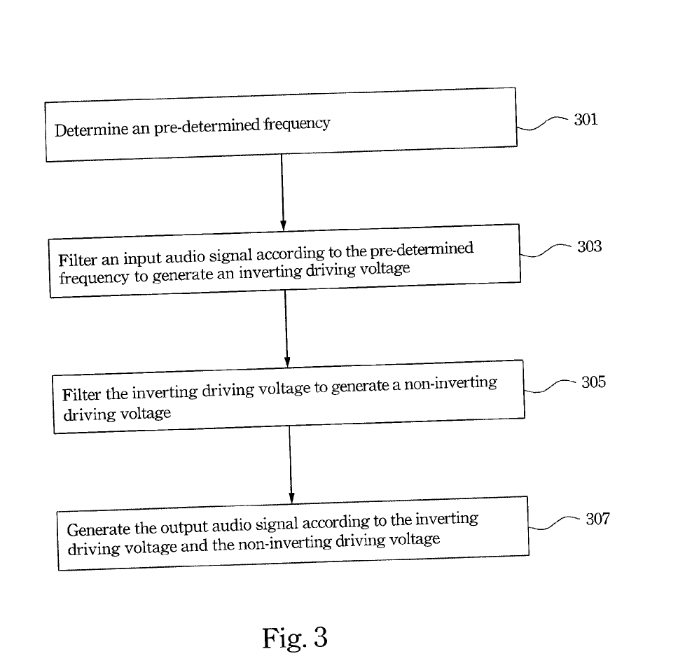

FIG. 3 shows the flow chart of a method for playing the audio signal according to the embodiment of the present invention. The method first determines the pre-determined frequency (step 301). The pre-determined frequency distinguishes the passing frequencies and the rejected frequencies. Signals with frequencies greater than the pre-determined frequency are rejected. With proper pre-determined frequency, pop noises can be eliminated.

After the pre-determined frequency has been determined, the method filters the input audio signal according to the pre-determined frequency to generate the inverting driving voltage (step 303), in which the input audio signal with frequencies greater than the pre-determined frequency is filtered out. Then the method filters the inverting driving voltage again to generate the non-inverting driving voltage (step 305). After step 305, the method generates the output audio signal according to the inverting driving voltage and the non-inverting driving voltage (step 307).

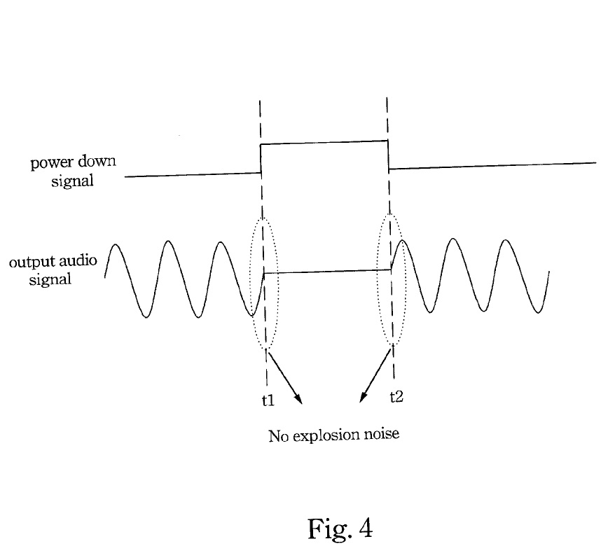

FIG. 4 shows the power down signal waveform and the output audio signal waveform of the audio amplifier according to the embodiment of the present invention. According to the waveform, we can see that the explosion noises of the output audio signal are reduced when the power down signal is asserted at time t1 and de-asserted at time t2 by adding the filtering circuit.

According to the above embodiments, the filtering circuit of the audio amplifier can filter out signals with frequencies greater than the pre-determined frequency, such that the pop noise of the output audio signal can be filtered out and eliminated.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An audio amplifier for amplifying an audio signal, comprising:
a first filtering circuit generating an inverting driving voltage to drive a load according to the audio signal, wherein the first filtering circuit filters out signals with frequencies greater than a pre-determined frequency; and
a second filtering circuit generating an non-inverting driving voltage to drive the load according to the inverting driving voltage, wherein the second filtering circuit filters out the signals with frequencies greater than the pre-determined frequency.

2. The audio amplifier as claimed in claim 1, wherein the first filtering circuit comprises:
a first operation amplifier generating the inverting driving voltage according to the audio signal;
a first resistor having one end receiving the audio signal and the other end connected to a negative terminal of the first operation amplifier; and
a first capacitor connected between the negative terminal and an output terminal of the first operation amplifier,
wherein the capacitance of the first capacitor and the resistance of the first resistor determine the pre-determined frequency.

3. The audio amplifier as claimed in claim 2, wherein the first filtering circuit further comprises a second resistor connected between the negative terminal and the output terminal of the first operation amplifier.

4. The audio amplifier as claimed in claim 2, wherein the first operation amplifier is a class AB amplifier, a class B amplifier, or a class A amplifier.

5. The audio amplifier as claimed in claim 1, wherein the second filtering circuit comprises:
a second operation amplifier generating the non-inverting driving voltage according to the inverting driving voltage;
a third resistor having one end receiving the inverting driving voltage and the other end connected to a negative terminal of the second operation amplifier; and
a second capacitor connected between the negative terminal and an output terminal of the second operation amplifier,
wherein the capacitance of the second capacitor and the resistance of the third resistor determine the pre-determined frequency.

6. The audio amplifier as claimed in claim 5, wherein the second operation amplifier is a class AB amplifier, a class B amplifier, or a class A amplifier.

7. The audio amplifier as claimed in claim 5, wherein the second filtering circuit further comprises a fourth resistor connected between the negative terminal and the output terminal of the second operation amplifier.

8. The audio amplifier as claimed in claim 1, further comprising:
a bias control circuit providing at least one bias voltage for the first filtering circuit and the second filtering circuit, wherein the first filtering circuit and the second filtering circuit generate the inverting driving voltage and the non-inverting driving voltage in accordance with the bias voltage; and
a decoupling device for reducing the damping phenomenon of the bias voltage caused by powering on or powering down the audio amplifier.

9. The audio amplifier as claimed in claim 8, wherein the decoupling device comprises a decoupling capacitor having one end coupled to the bias control circuit and the other end receiving a ground voltage.

10. The audio amplifier as claimed in claim 8, wherein the decoupling device comprises a decoupling capacitor having one end coupled to the bias control circuit and the other end receiving a supply voltage.

11. The audio amplifier as claimed in claim 1, wherein the load driven by the inverting driving voltage and the non-inverting driving voltage is a speaker.

12. A method for generating an output audio signal, comprising:
determining a pre-determined frequency;
filtering an input audio signal according to the pre-determined frequency to generate an inverting driving voltage, wherein the input audio signal with frequency greater than the pre-determined frequency is filtered out;
filtering the inverting driving voltage again to generate a non-inverting driving voltage; and
generating the output audio signal according to the inverting driving voltage and the non-inverting driving voltage.

13. The method for generating the output audio signal as claimed in claim 12, wherein the pre-determined frequency is less than a pop noise frequency.

14. The method for generating the output audio signal as claimed in claim 12, wherein a speaker is used to generate the output audio signal.

15. The method for generating the output audio signal as claimed in claim 12, wherein a filtering circuit is used to filter the input audio signal.

16. The method for generating the output audio signal as claimed in claim 15, wherein the resistance and the capacitance of the filtering circuit are tuned to filter out the input audio signal with frequency greater than the pre-determined frequency.
